(19) United States
(12) Patent Application Publication
(10) Pub. No.: US 2006/0138578 A1
(43) Pub. Date: Jun. 29, 2006

(54) CMOS image sensor and method for fabricating the same

(76) Inventor: Keun Hyuk Lim, Seoul (KR)

Correspondence Address: MCKENNA LONG & ALDRIDGE LLP, 1900 K STREET, NW, WASHINGTON, DC, 20006, US

(21) Appl. No.: 11/318,445

(22) Filed: Dec. 28, 2005

(30) Foreign Application Priority Data
Dec. 29, 2004 (KR) 10-2004-0114791

(51) Int. Cl. H01L 31/0232

(52) U.S. Cl. 257/432

(57) ABSTRACT

A CMOS image sensor and a method for fabricating the same in which characteristics of the image sensor are not affected even if a profile of microlenses is varied, so as to obtain a more reliable device. The CMOS image sensor of the present invention includes color filter layers formed over a semiconductor substrate, a planarization layer formed on the color filter layers, and microlenses formed of the same material as that of the planarization layer on the planarization layer, the microlenses positioned to correspond to the color filter layers respectively.

### CROSS REFERENCE TO RELATED APPLICATION

This application claims the benefit of the Korean Patent Application No. P2004-114791, filed on Dec. 29, 2004, which is hereby incorporated by reference as if fully set forth herein.

### BACKGROUND OF THE INVENTION

1. Field of the Invention

The present invention relates to a complementary metal-oxide semiconductor (CMOS) image sensor and a method for fabricating the same, and more particularly, to a CMOS image sensor and a method for fabricating the same in which better reliability of a device is obtained.

2. Discussion of the Related Art

Generally, an image sensor is a semiconductor device that converts optical images to electrical signals. An image sensor may include a charge coupled device (CCD) or a CMOS image sensor.

The CCD includes a plurality of photodiodes (PD) arranged in a matrix to convert optical signals to electrical signals, a plurality of vertical charge coupled devices (VCCDs) formed between the photodiodes in a vertical direction to transfer charges generated by the respective photodiodes in a vertical direction, a plurality of horizontal charge coupled devices (HCCDs) transferring the charges transferred by the VCCDs in a horizontal direction, and a sensing amplifier sensing the charges transferred in a horizontal direction to output electrical signals.

The aforementioned CCD has the drawbacks of requiring a complicated driving mode, high power consumption, and multistage photolithographic processes.

Furthermore, it is difficult to integrate a control circuit, a signal processing circuit, and an analog-to-digital converter in a CCD chip. This prevents the manufacture of slim products.

To overcome the drawbacks of CCD, the CMOS image sensor has been given much attention as an image sensor for next generation.

The CMOS image sensor employs a switching mode that sequentially detects outputs of unit pixels using MOS transistors by forming the MOS transistors corresponding to the number of the unit pixels on a semiconductor substrate using a control circuit and a signal processing circuit as peripheral circuits.

The CMOS image sensor sequentially detects electrical signals of each unit pixel using a switching mode to display images by forming photodiodes and MOS transistors in unit pixels.

The CMOS image sensor has the advantages of low power consumption and a simple fabrication process that involves only a relatively small number of photolithographic process steps.

Furthermore, since the CMOS image sensor allows a control circuit, a signal processing circuit and an analog-to-digital converter to be integrated in its chip, it has the advantage of allowing for the manufacture of slim products.

In fact, CMOS image sensors have found a wide use in various applications such as digital still camera and digital video camera.

The CMOS image sensor is divided into a 3T type, a 4T type, and 5T type depending on the number of transistors. The 3T type CMOS image sensor is comprised of a photodiode and three transistors while the 4T type CMOS image sensor is comprised of a photodiode and four transistors.

FIG. 1 is an exemplary circuit diagram illustrating a general 3T type CMOS image sensor, and FIG. 2 is an exemplary layout illustrating a typical 3T type CMOS image sensor.

A unit pixel of the 3T type CMOS image sensor, as shown in FIG. 1, includes a photodiode PD and three nMOS transistors T1, T2 and T3. A cathode of the photodiode is connected to a drain of the first nMOS transistor T1 and a gate of the second nMOS transistor T2.

Sources of the first and second nMOS transistors T1 and T2 are connected to a power line supplied with a reference voltage VR. A gate of the first NMOS transistor T1 is connected to a reset line supplied with a reset signal RST.

A source of the third nMOS transistor T3 is connected to a drain of the second nMOS transistor T2, its drain is connected to a reading circuit (not shown) through a signal line, and its gate is connected to a heat selection line supplied with a heat selection signal SLCT.

The first nMOS transistor T1 is called a reset transistor Rx, the second nMOS transistor T2 is called a drive transistor Dx, and the third nMOS transistor T3 is called a selection transistor Sx.

In a unit pixel of a 3T type CMOS image sensor, as shown in FIG. 2, a photodiode 20 is formed in a wide portion of an active area 10, and gate electrodes 120, 130, and 140 of three transistors overlapped with one another are formed in the remaining portion of active area 10.

The reset transistor Rx is formed by the gate electrode 120, the drive transistor Dx is formed by the gate electrode 130, and the selection transistor Sx is formed by the gate electrode 140.

Source and drain areas of each transistor are formed by implanting impurity ions into the active area 10 at each transistor except for the portions below the gate electrodes 120, 130 and 140.

A power voltage Vdd is applied to the source and drain areas between the reset transistor Rx and the drive transistor Dx, and the source and drain areas at one side of the selection transistor Sx are connected to a reading circuit (not shown).

Although not shown, each gate electrode 120, 130 and 140 is connected to a signal line. Each signal line is provided with a pad at one end to be connected to an external driving circuit.

Process steps performed after the formation of each signal line provided with the pad will be described as follows.

FIG. 3A to FIG. 3D are sectional views illustrating a method for fabricating CMOS image sensor according to the related art.

First, as shown in FIG. 3A, an insulating layer 101 (for example, oxide layer) such as a gate insulating layer or a dielectric interlayer is formed on a semiconductor substrate 100. A metal pad 102 of each signal line is formed on the insulating layer 101.

A passivation layer 103 is formed on an entire surface of the insulating layer 101 and on the metal pad 102.

Subsequently, the passivation layer 103 is selectively removed to partially expose the surface of the metal pad 102. A cap oxide layer 104 is then formed over the entire surface of the semiconductor substrate 100.

As shown in FIG. 3B, color filter layers 105 are formed on the cap oxide layer 104 to correspond to each photodiode area (not shown).

Subsequently, a planarization layer 106 is formed over the entire surface of the semiconductor substrate 100. The planarization layer 106 is then selectively removed by a photolithographic process to remain only on the color filter layers 105.

As shown in FIG. 3C, microlenses 107 are formed on the planarization layer 106 to correspond to the respective color filter layers 105.

As shown in FIG. 3D, a blanket etching process is performed on the entire surface of the cap oxide layer 104 to expose the surface of the metal pad 102 and to form a pad opening portion 108.

During this blanket etching process of the cap oxide layer 104 however, the microlenses 107 are damaged. For this reason, a profile of the microlenses 107 is varied as shown by “A” in FIG. 3D.

Variation of the profile of the microlenses affects the characteristics of the image sensor and deteriorates the reliability of the device.

### SUMMARY OF THE INVENTION

Accordingly, the present invention is directed to a CMOS image sensor and a method for fabricating the same that substantially obviates one or more problems due to limitations and disadvantages of the related art.

One advantage of the present invention is that it can provide a CMOS image sensor and a method for fabricating the same, in which characteristics of the image sensor are not affected even if a profile of microlenses is varied, so as to obtain a more reliable device.

Additional examples of advantages and features of the invention will be set forth in part in the description which follows and in part will become apparent to those having ordinary skill in the art upon examination of the following or may be learned from practice of the invention.

To achieve these and other advantages and in accordance with an embodiment of the invention, as embodied and broadly described herein, a CMOS image sensor according to the present invention includes color filter layers formed over a semiconductor substrate, a planarization layer formed on the color filter layers, and microlenses formed on the planarization layer, wherein the microlenses are formed of the same material as that of the planarization layer, and are positioned to correspond to the color filter layers.

In another aspect of the present invention, a method for fabricating a CMOS image sensor includes forming color filter layers over a semiconductor substrate, forming a planarization layer on the color filter layers, and forming microlenses on the planarization layer, wherein the microlenses are formed of the same material as that of the planarization layer in such a way that the microlenses are positioned to correspond to the color filter layers.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principles of the invention.

In the drawings:

FIG. 1 is an equivalent circuit diagram illustrating a typical CMOS image sensor:

FIG. 2 is a layout illustrating a typical CMOS image sensor;

FIG. 3A to FIG. 3D are sectional views illustrating a method for fabricating a related art CMOS image sensor;

FIG. 4 is a sectional view illustrating a CMOS image sensor according to an embodiment of the present invention; and

FIG. 5A to FIG. 5E are sectional views illustrating a method for fabricating a CMOS image sensor according to an embodiment of the present invention.

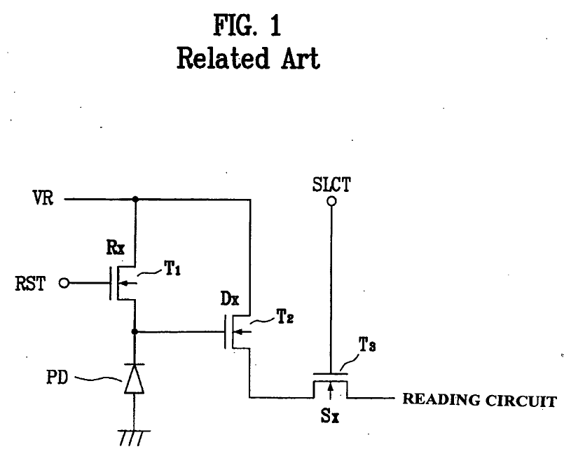

### DETAILED DESCRIPTION OF THE INVENTION

Reference will now be made in detail to some embodiments of the present invention, examples of which are illustrated in the accompanying drawings. Wherever possible, the same reference numbers will be used throughout the drawings to refer to the same or like parts.

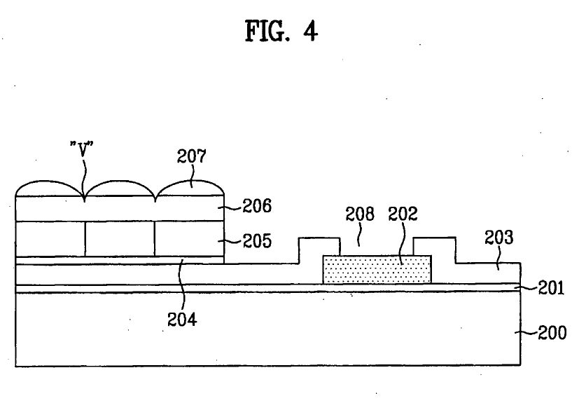

FIG. 4 is a sectional view illustrating an exemplary CMOS image sensor according to the present invention.

As shown in FIG. 4, a CMOS image sensor according to the present invention includes an insulating layer 201 formed on a semiconductor substrate divided into an active area and a pad area, a metal pad 202 formed in the pad area on the insulating layer 201, a passivation layer 203 formed with a pad opening portion 208 to partially expose a surface of the metal pad 202, a cap oxide layer 204 formed in the active area on the passivation layer 203, color filter layers 205 formed on the cap oxide layer 204, a planarization layer 206 formed on the color filter layers 205, and microlenses 207, formed of the same material as that of the planarization layer 206, on the planarization layer 206 to correspond to the color filter layers 205.

The planarization layer 206 and the microlenses 207 are formed of either photoresist layers or TEOS layers.

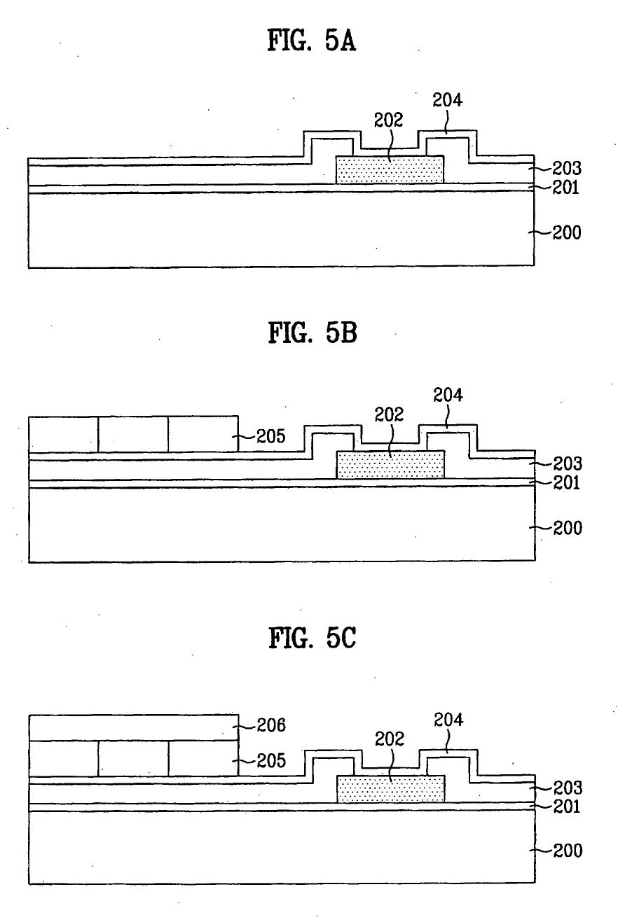

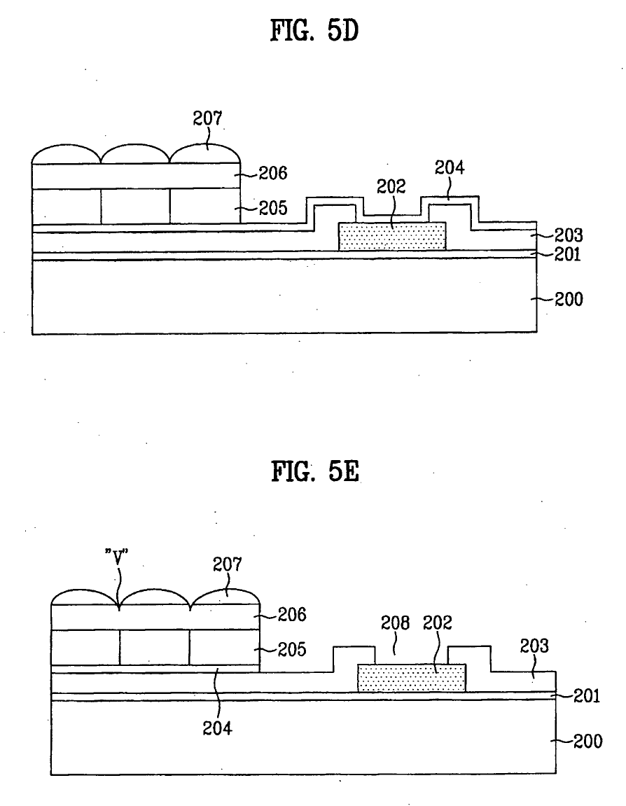

FIG. 5A to FIG. 5E are sectional views illustrating a method for fabricating the CMOS image sensor according to the preferred embodiment of the present invention.

As shown in FIG. 5A, the insulating layer 201 such as a gate insulating layer or a dielectric interlayer is formed on the semiconductor substrate 200. A metal pad 202 of each signal line is formed on the insulating layer 201.

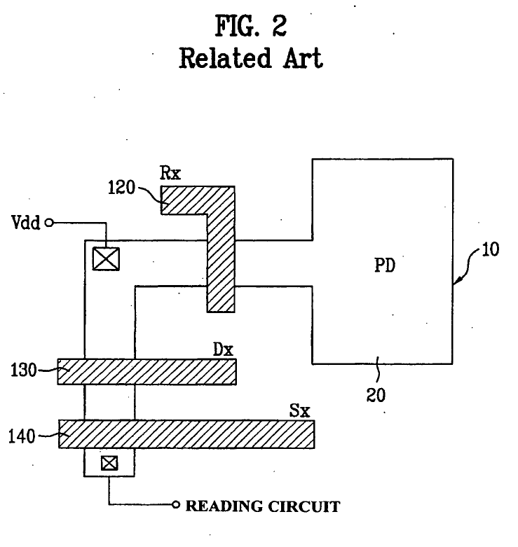

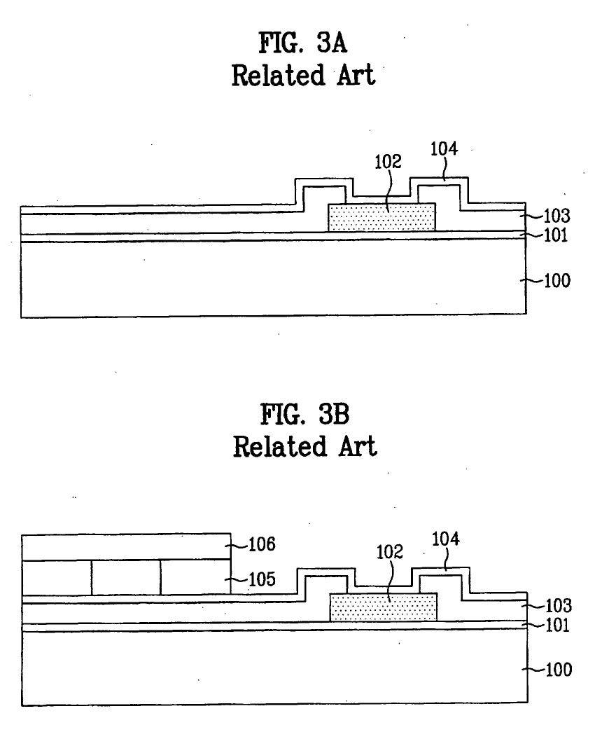

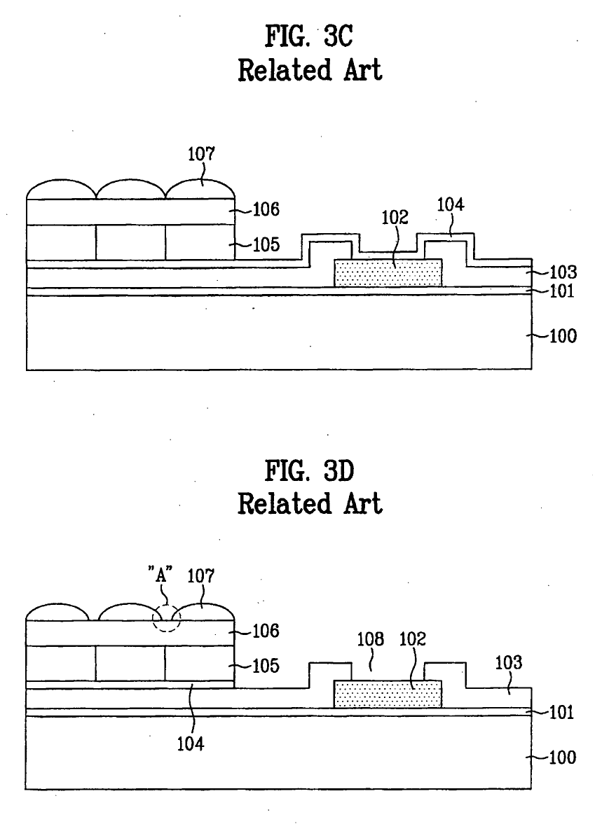

The metal pad 202 may be formed of the same material as that of gate electrodes 120, 130 and 140 shown in FIG. 2 and on the same layer as the gate electrodes 120, 130 and 140. Alternatively, the metal pad 202 may be formed of a material different from that of the gate electrodes 120, 130 and 140 and connected through a separate contact hole. In most cases, the metal pad 202 may be formed of aluminum (Al).

A surface of the metal pad 202 is treated with UV ozone or mixture of solutions to improve corrosion resistance of the metal pad 102.

The passivation layer 203 is formed over an entire surface of the semiconductor substrate 200 including the metal pad 202. The passivation layer 203 is then selectively removed to partially expose the surface of the metal pad 202.

Subsequently, the cap oxide layer 204 is formed over the entire surface of the semiconductor substrate 200 including the passivation layer 203.

The cap oxide layer 204 has a thickness of approximately 300 Å-800 Å. The cap oxide layer 204 protects the metal pad 202 from corrosion, which may be caused by a developing solution during the exposure and development processes performed during the formation of the color filter layers.

As shown in FIG. 5B, the color filter layers 205 are formed on the cap oxide layer 204 to correspond to each photodiode area (not shown).

The color filter layers 205 are formed as follows. A blue color resist is deposited and then patterned by photolithography to form a blue color filter layer. A green and red color filter layers are then respectively formed in the same manner.

As shown in FIG. 5C, a planarization layer 206 is formed over the entire surface of the semiconductor substrate 200 including the color filter layers 205. The planarization layer 206 may be formed of the same material as that of the microlenses that will be formed later, which may be a photoresist or TEOS material.

Subsequently, the planarization layer 206 is selectively removed by a photolithographic process to remain only in an area that does not include the metal pad.

UV baking may additionally be performed over the planarization layer 206.

As shown in FIG. 5D, the same material as that of the planarization layer 206 may be deposited over the entire surface of the semiconductor substrate 200 including the planarization layer 206, and a microlens pattern may be formed by a photolithography process.

Subsequently, the microlens pattern undergoes a reflow process at a predetermined temperature to form microlenses 207 of a semispherical shape.

As shown in FIG. 5E, a blanket etching process is performed on the entire surface of the semiconductor substrate 200 to selectively remove the cap oxide layer 204 on the pad area, thereby forming the pad opening portion 208.

During the blanket etching process of the cap oxide layer 204, the microlenses 207 are damaged. For this reason, a profile of the microlenses 207 is varied, in which the microlenses 207 become thin. However, since the planarization layer 206 is formed of the same material as that of the microlenses 207, the planarization layer 206 between the microlenses 207 may be selectively etched to form a V-shape groove of a desired depth. In this manner, the varied profile of the microlenses 207 can be compensated.

As described above, the CMOS image sensor and the method for fabricating the same according to the present invention has many advantages.

Since the thin portion of the microlenses, which is caused by the blanket etching process of the cap oxide layer, can be compensated by removing the planarization layer formed between the microlenses, it is possible to prevent deterioration of the reliability of the device.

In addition, since the planarization layer is formed of the same material as that of the microlenses, it is possible to prevent a space of the microlenses from becoming large.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A CMOS image sensor comprising:
color filter layers formed over a semiconductor substrate;
a planarization layer formed on the color filter layers; and
microlenses formed on the planarization layer, wherein the microlenses are formed of the same material as that of the planarization layer, and are positioned to correspond to the color filter layers.

2. The CMOS image sensor according to claim 1, further comprising:
a metal pad formed in a pad area on the semiconductor substrate divided into an active area and a pad area;
a passivation layer formed with a pad opening portion to partially expose a surface of the metal pad; and
a cap oxide layer formed in the active area on the passivation layer,
wherein the color filter layers are formed on the cap oxide layer.

3. The CMOS image sensor according to claim 2, wherein the metal pad is formed of aluminum.

4. The CMOS image sensor according to claim 2, wherein the cap oxide layer has a thickness of approximately 300 Å-800 Å.

5. The CMOS image sensor according to claim 1, wherein the planarization layer and the microlenses are formed of photoresist layers or TEOS layers.

6. A method for fabricating a CMOS image sensor comprising:
forming color filter layers over a semiconductor substrate;
forming a planarization layer on the color filter layers; and
forming microlenses on the planarization layer, wherein the microlenses are formed of the same material as that of the planarization layer in such a way that the microlenses are positioned to correspond to the color filter layers.

7. The method according to claim 6, further comprising:
forming a metal pad in a pad area on the semiconductor substrate divided into an active area and the pad area;
forming a passivation layer on an entire surface of the semiconductor substrate including the metal pad;
selectively removing the passivation layer to expose a surface of the metal pad;
forming a cap oxide layer on the entire surface of the semiconductor substrate including the metal pad, wherein the color filter layers are formed on the cap oxide layer over the active area; and
selectively removing the cap oxide layer over the pad area to form a pad opening portion.

8. The method according to claim 7, further comprising forming an insulating layer between the semiconductor substrate and the metal pad.

9. The method according to claim 7, wherein the metal pad is formed of aluminum.

10. The method according to claim 7, wherein the cap oxide layer has a thickness of approximately 300 Å-500 Å.

11. The method according to claim 7, wherein the cap oxide layer is selectively removed by a blanket etching process.

12. The method according to claim 7, further comprising treating a surface of the metal pad with UV ozone.

13. The method according to claim 6, wherein the planarization layer and the microlenses are formed of photoresist layers or TEOS layers.

14. The method according to claim 6, further comprising performing UV baking over the planarization layer.
